(19) United States
(12) Patent Application Publication
(10) Pub. No.: US 2018/0294155 A1
(43) Pub. Date: Oct. 11, 2018

(54) PROCESS FOR OBTAINING SEMICONDUCTOR NANODEVICES WITH PATTERNED METAL-OXIDE THIN FILMS DEPOSITED ONTO A SUBSTRATE, AND SEMICONDUCTOR NANODEVICES THEREOF

(71) Applicant: Centre National De La Recherche Scientifique, Paris Cedex 16 (FR)

(72) Inventors: Olivier Soppera, Mulhouse (FR); Hsiao-Wen Zan, Hsinchu-City - Chinese Taipei (TW); Hung-Cheng Lin, Hsinchu-City - Chinese Taipei (TW); Chang-Hung Li, New Taipei City - Chinese Taipei (TW); Fabrice Stehlin, Moernach-France (FR); Arnaud Spangenberg, Flaxladen (FR); Fernand Wleder, Muespach-le-Haut (FR); Chung-Chen Yeh, Taipei City (TW)

(21) Appl. No.: 15/572,059

(22) PCT Filed: May 3, 2016
(86) PCT No.: PCT/EP2016/059824

§ 371 Date: Nov. 6, 2017

(30) Foreign Application Priority Data
May 4, 2015 (EP) 15166292.1

(51) Int. Cl. H01L 21/02; G03F 7/20; G03F 7/16; G03F 7/30

(52) U.S. Cl. CPC H01L 21/02565; G03F 7/70025; G03F 7/168; H01L 21/02628; H01L 21/0257; H01L 21/0259; G03F 7/30

(57) ABSTRACT

Processes for obtaining a semiconductor nanodevice comprising a substrate, onto which patterned metal-oxide thin films having semiconductor properties are deposited, are provided, as well as semiconductor devices comprising them. The present invention belongs to the field of semiconductor nanodevices.

### TECHNICAL FIELD OF THE INVENTION

The present invention relates to processes for obtaining patterned metal-oxide thin films deposited onto substrates, the filmed substrates obtained thereof, and semiconductor devices comprising them. The present invention belongs to the field of semiconductor nanodevices.

### BACKGROUND

In many fields, such as in electronics, optics, photonics, photovoltaic, photocatalysis, biology, electrochemistry and electromechanics, there is an increasing need in providing semiconductor nanodevices, i.e. semiconductor articles having lateral dimensions and thicknesses ranging from about lnm to about 100 nm. These articles may be used in many different applications, particularly in active-matrix displays, such as displays, sensor arrays, solar-cells, transistors, and X-ray detectors.

Over the past years, it has been shown particularly interesting to obtain devices comprising a substrate and a patterned metal-oxide thin film deposited onto it. The deposited patterned metal-oxide thin film usually has semiconductor properties, and is associated with various advantages. For practical applications, a patterning is required, with size structures ranging from mm to nm scales, depending on the final device properties. Particularly, such nanostructures may be processed as solution, easing the manufacturing process. They also exhibit a high transparency in visible light, allowing the manufacturing of transparent electronics. They are also robust, with a satisfactory inertness towards chemical, temperatures, and pressure. They exhibit also for example high electron mobility, flexibility, and good air stability.

It is known already various processes for obtaining patterned metal-oxide thin films deposited onto a substrates. Such processes aim at tackling various needs and/or issues, including the implementation of simple and low-cost, non-vacuum, and/or photoresist-free processes; controllability of the shape, size, uniformity, and/or thickness of the deposited films; reduction of process steps; avoidance of toxic and high-cost chemicals; compatibility with temperature sensitive substrates e.g. plastic substrates. Suitable processes for obtaining semiconductor metal oxide nanostructures have been disclosed for example in the following publications: Y. H. Kim, Nature, vol. 489, 6 Sep. 2012, 128; Y.-H. Lin, Adv. Mater. 2013, 25, 4340-4346; Y. S. Rim et al., ACSNANO, vol. 8, n° 9, 9680-9686, 2014); H. S. Lim et al., Scientific Reports, 4:4544, D01:10.1038/srep04544; J. H. Kim et al., ACS Appl. Mater. Interfaces 2014, 6, 4819-4822. One of the drawbacks associated with these known technologies lies on the low photosensitivity of the proposed precursor solution at the working wavelength, limiting particularly the possibility of resolution by photopatterning.

There is the constant need thereof for providing improved processes for obtaining semiconductor nanodevices comprising a substrate, wherein a patterned metal-oxide thin films is deposited onto said substrate.

There is also the need for obtaining semiconductor nanodevices comprising a substrate, onto which a patterned metal-oxide thin films is deposited, and exhibiting superior semiconductor properties.

There is also the need of obtaining semiconductor nanodevices comprising a substrate, onto which a patterned metal-oxide thin films is deposited onto a substrate, and being adapted to applications requiring high resolution.

There is also the need of providing a process, being of lower cost and simpler implementation, particularly a process requiring using less materials.

### SUMMARY OF THE INVENTION

According to a first aspect, the present invention relates to a process for obtaining semiconductor nanodevices comprising a substrate. Patterned metal-oxide thin films are deposited onto said substrate. Said patterned metal-oxide thin films have semi conductor properties. Said process comprising the steps of:
preparing a metal oxide chelate solution by complexing metal oxide precursors with a ligand in an alcoholic solvent for obtaining a metal oxide chelate;
preparing a metal oxo-cluster solution by submitting the metal oxide chelate solution to water hydrolysis, for obtaining a partially-condensed metal oxide chelate;
preparing a doped-metal oxide solution by doping the metal oxo-cluster solution with a doping material comprising a metal element;
depositing the doped-metal oxide solution onto a substrate, for obtaining a substrate coated with a metal oxide thin film;
patterning the coated substrate by irradiating it with deep ultra-violet (DUV) wavelengths, for obtaining a patterned coating;
immersing the substrate comprising a patterned coating into a development media, for obtaining a developed patterned substrate;
post-annealing or post-exposing by DUV the developed patterned substrate, for obtaining a fully inorganic patterned substrate.

The ligand is methacrylic acid.

The metal oxide precursors comprise metal elements selected from the group consisting of zirconium (Zr), titanium (Ti), zinc (Zn), and mixtures thereof.

The coated substrate is irradiated via a laser emitting DUV wavelengths.

The inventors have provided an improved process for obtaining a patterned metal-oxide thin film deposited onto a substrate, by carefully selecting the process steps to be carried out, and the materials to be used. The patterned metal-oxide thin film deposited exhibit semiconductor properties, and it is obtained a semiconductor nanodevice. In particularly, the inventors have demonstrated the superiority of a process comprising—amongst other steps—a complexation step using a specific ligand, then a partial condensation step, then an irradiation step with DUV wavelengths, and then a post-annealing or post-exposing DUV step.

Indeed, the use of methacrylic acid as a ligand in the complexation step has shown particularly beneficial when carrying out subsequently an irradiation step with DUV wavelengths, as methacrylic acid bounded to transition metal exhibits high sensitivity in the DUV range, allowing light-induced crosslinking. Using methacrylic acid allows obtaining therefore metal oxide chelate being particularly suitable for use with DUV light source, especially considering the high optical absorption at specific wavelengths. It further allows mitigating the loss of resolution, which may be observed when using a DUV light source, particularly because of the incident heating, spreading to the non-irradiated parts of the substrate, inducing unwanted crosslinking. In addition, the implementation of a partial condensation step has shown particularly useful, when combined with a complexation step using a specific ligand and a partial condensation step, in that it prevents dewetting to occur.

In addition, the preparation of metal oxo clusters as host matrixes enables an efficient conversion from the solution to the solid state by thermal and/or photochemical annealing, the metal oxo-cluster acting as the precursor of the final metal oxide network. The metal oxide network is thus preformed in molecular scale species. Moreover, the control of the size of the metal oxo-cluster guarantees nanoscale resolution. The control of the surface chemistry of the metal oxo-clusters allows finely tuning the affinity of the clusters to the surface of the substrate, which is another important parameter for any application.

The implementation of the irradiation step with a laser emitting DUV wavelengths allows the use of nanolithography, for obtaining semiconductor nanodevices. Indeed, the use of a laser, in comparison with a lamp, avoids, or at least greatly prevents, the occurrence of thermal effects leading particularly to the reticulation of non-irradiated parts of the substrate, leading therefore to a loss of resolution.

The use of photochemical process of the present invention, for preparing the final material, has shown several advantages. Firstly, the semiconductor nanostructures can be prepared by direct write, which considerably simplifies the process of integration and enables the integration of the semiconducting material upon specific conditions (flexible substrates, atmospheric conditions, etc.). Secondly, the DUV irradiation of the material allows freezing the material at room temperature, helping thereof controlling the homogeneity of the material at atomic scale and thus its physical properties (namely electrical properties).

By the term nanodevice”, it is meant a device composed of functional structures with width and/or thickness in the range of lnm to 100 nm. The present invention is not concerned with microdevices.

By the term “semiconductor device”, it is meant a device with a medium resistivity and with conductance that can be varied depending on the current or voltage applied to a control electrode, or on the intensity of irradiation by infrared (IR), visible light, ultraviolet (UV), or X rays. The devices of the present invention are not suitable for use as insulating devices.

The metal oxide precursors may comprise metal elements selected from the group consisting of zirconium (Zr), titanium (Ti), hafnium (HD, zinc (Zn), aluminium (Al), and mixtures thereof; alternatively selected from the group consisting of Zr, Ti, Zn, and mixtures thereof; alternatively selected from the group consisting of Zr, Ti, and mixtures thereof.

The metal oxide precursors may be selected from the group consisting of metal alcoxide, metal acetate, metal citrate dihydrate, metal acetate dihydrate, metal acetylacetonate hydrate, metal acrylate, metal chloride, metal diethyldithiocarbamate, metal dimethyldithiocarbamate, metal fluoride, metal fluoride hydrate, metal hexafluoroacetylacetonate dihydrate, metal methacrylate, metal nitrate hexahydrate, metal nitrate hydrate, metal trifluoromethanesulfonate, metal undecylenate, metal trifluoroacetate hydrate, metal tetrafluoroborate hydrate, metal perchlorate hexahydrate, and mixtures thereof; alternatively selected from the group consisting of metal alcoxide; alternatively selected from the group consisting of metal propoxide, metal isopropoxide, and mixtures thereof; alternatively selected from the group consisting of Zr(O-i-Pr)₄, Hf(O-i-Pr)₄, Ti(O-i-Pr)₄, Zn(O-i-Pr)₄, Al(O-i-Pr)₄ and mixtures thereof; alternatively selected from the group consisting of Zr(O-i-Pr)₄, Ti(O-i-Pr)₄, Zn(O-i-Pr)₄ and mixtures thereof; and alternatively selected from the group consisting of Zr(O-i-Pr)₄, Ti(O-i-Pr)₄, and mixtures thereof.

The alcoholic solvent may be selected from the group consisting of propanol, isopropanol, 2-methoxyethanol, ethanol, methanol, dimethylformamide, acetylacetone, dimethylamineborane, acetonitrile, cyclohexane, and mixtures; alternatively selected from the group consisting of propanol, isopropanol, 2-methoxyethanol, ethanol, methanol and mixtures thereof; alternatively the alcoholic solvent is propanol.

The doping material comprises a metal element, wherein the metal element may be selected from the group consisting of indium (In), gallium (Ga), tin (Sn), thallium (Tl), copper (Cu), aluminium (Al), and mixtures thereof; alternatively wherein the metal element may be In.

The doping material may be selected from the group consisting of metal nitrate, metal chloride, metal chloride tetrahydrate, metal fluoride, metal fluoride trihydrate, metal hydroxide, metal acetate hydrate, metal acetylacetonate, metal acetate, metal chloride pentahydrate, metal cyclopentadienide, metal formate, metal hexafluoroacetylacetonate, metal trifluoroacetate, metal perchlorate hydrate, and mixtures thereof; alternatively the doping material may be metal nitrate.

In a particular embodiment, the doping material is In(NO₃)₃.

The technique for depositing the metal oxide thin film onto the substrate may be chosen from the group consisting of spin-coating, dip-coating, spray-coating, inkjet, screen-printing; alternatively the technique for depositing the metal oxide thin film onto the substrate from the group may consist of spin-coating.

The deposition of the metal oxide thin film onto the substrate may be conducted at room temperature, under atmospheric conditions, and under controlled humidity.

It may be obtained a thin film deposited onto the substrate, wherein said thin film has a thickness ranging from about 10 nm to about 500 nm; preferably from about 20 nm to about 200 nm; more preferably from about 80 nm to about 120 nm.

The substrate may be made of suitable materials. The substrate may be selected from the group consisting of glass, silicon, silicon dioxide, aluminium oxide, sapphire, germanium, gallium arsenide, an alloy of silicon and germanium, indium phosphide, plastic such as polyimide), textiles or their combinations thereof; alternatively the substrate is silicon.

The technique for irradiating the film substrate may be a spatially-controlled irradiation; alternatively the technique may be photolithography using DUV lamp or lasers; alternatively the technique may be laser direct write lithography or interference lithography.

In a particular embodiment, the coated substrate is irradiated via a laser emitting DUV wavelengths. The coated substrate may be irradiated at a UV wavelengths of about 300 nm or less; alternatively at a UV wavelengths ranging from about 180 nm to about 270 nm; alternatively at a UV wavelengths of about 193 nm+/−about 0.5 nm or at a UV wavelengths of about 244 nm+/−about 0.5 nm.

The development media may be an organic solvent; alternatively the development media may be selected from the group consisting of an alcohol, cyclohexanone, and mixtures thereof; alternatively from the group consisting of ethanol, 2-methoxyethanol, propanol, isopropanol, cyclohexanone and mixtures thereof. In an alternative, the development may be an aqueous solution; alternatively an acid aqueous solution or a basic aqueous solution.

The patterned substrate may be immersed into the organic solvent from 1 sec to 180 sec.

The developed patterned substrate may be post-annealed by thermal and/or photochemical treatment.

The thermal treatment may be carried out at a temperature ranging from about 100° C. to about 800° C.; preferably at a temperature ranging from about 250° C. to about 600° C.; more preferably at a temperature ranging from about 300° C. to about 450° C. Simultaneously to the thermal treatment, a photochemical treatment may be applied using a DUV laser or DUV lamp.

In one embodiment, the present invention relates to a process for obtaining a semiconductor nanodevice comprising a substrate, substrate onto which patterned metal-oxide thin films having semiconductor properties are deposited, said process comprising the steps of:
preparing a metal oxide chelate solution by complexing metal oxide precursors comprising metal elements selected from the group consisting of zirconium (Zr), titanium (Ti), zinc (Zn) and mixtures thereof; preferably from the group consisting of zirconium (Zr), titanium (Ti), and mixtures thereof; with a ligand being methacrylic acid in an alcoholic solvent being propanol, for obtaining a metal oxide chelate;
preparing a metal oxo-cluster solution by submitting the metal oxide chelate solution to water hydrolysis, for obtaining a partially-condensed metal oxide chelate;
preparing a doped-metal oxide solution by doping the metal oxo-cluster solution with a doping material being In(NO₃)₃;
depositing by spin-coating the doped-metal oxide solution onto a substrate of silicone, for obtaining a substrate coated with a semiconductor thin film having a thickness from about 80 nm to about 120 nm;
patterning the coated substrate by irradiating it with deep ultra-violet (DUV) wavelengths using a laser emitting DUV wavelengths, for obtaining a patterned coating;
immersing the substrate comprising a patterned coating into a development media, for obtaining a developed patterned substrate;
post-annealing the developed patterned substrate, for obtaining a fully inorganic patterned substrate.

According to a second aspect, the present invention relates to a semiconductor device comprising the substrate, onto which a patterned metal-oxide thin films is deposited, according to the first aspect of the invention.

### FIGURES

FIG. 1a is a photograph of a patterned metal-oxide thin film deposited onto the substrate (30×30 micron squares), when using an In-doped ZrO₂ solution (Zr:In molar ratio of 1:1) and mask lithography.

FIG. 1b is a photograph of a patterned metal-oxide thin film deposited onto the substrate (30×30 micron squares), when using an In-doped ZrO₂ solution (Zr:In molar ratio of 1:2) and mask lithography.

FIG. 1c is a photograph of a patterned metal-oxide thin film deposited onto the substrate (30×30 micron squares), when using an In-doped ZrO₂ solution (Zr:In molar ratio of 1:5) and mask lithography.

FIG. 2 is the graphic representation of the electric current density (A/cm2) of metal-oxide thin films deposited onto the substrate, in function of the voltage (V) for various ratio Zr:In.

FIG. 3 is a graphic representation of the absolute value of drain current (in log scale, Ampere) and the square root of the absolute value of the drain current (square root of Ampere) in function of the gate voltage (Volt) for various post-annealing temperatures.

FIG. 4a is an Atomic Force Microscopy image of a patterned metal-oxide thin film deposited onto the substrate, when using an In-doped ZrO₂ solution (Zr:In molar ratio of 1:0.2), and laser interferometry lithography, with line width of 300 nm.

FIG. 4b is an Atomic Force Microscopy image of a patterned metal-oxide thin film deposited onto the substrate, when using an In-doped ZrO₂ solution (Zr:In molar ratio of 1:0.2), and laser interferometry lithography, with line width of 300 nm.

### DETAILLED DESCRIPTION

The present process comprises the step of preparing a metal oxide chelate solution by complexing metal oxide precursors with a ligand in an alcoholic solvent, wherein the ligand is methacrylic acid. This step is called herein “complexation step”. It is obtained a metal oxide chelate.

The complexation step may be implemented by adding the ligand to the metal oxide precursor solution, then stirring the mixture obtained from about 1 min to about 60 min, then adding the alcoholic solvent to the stirred mixtures obtained, then stirring the mixture obtained from about 1 min to about 60 min.

The metal oxide precursors may comprise metal elements selected from the group consisting of zirconium (Zr), titanium (Ti), hafnium (HD, zinc (Zn), aluminium (Al), and mixtures thereof; alternatively selected from the group consisting of Zr, Ti, Zn, and mixtures thereof; alternatively selected from the group consisting of Zr, Ti, and mixtures thereof. The selection of these materials, particularly Zr and Ti, but also Zn, have shown particularly advantageous, in that they show a good stability over time, in that the films obtained have a good adhesion on most substrates, in that they form films with good optical quality and in that they provide improved photosensitivity allowing micro and nanoscale patterning.

The metal oxide precursors may be selected from the group consisting of metal alcoxide, metal acetate, metal citrate dihydrate, metal acetate dihydrate, metal acetylacetonate hydrate, metal acrylate, metal chloride, metal diethyldithiocarbamate, metal dimethyldithiocarbamate, metal fluoride, metal fluoride hydrate, metal hexafluoroacetylacetonate dihydrate, metal methacrylate, metal nitrate hexahydrate, metal nitrate hydrate, metal trifluoromethanesulfonate, metal undecylenate, metal trifluoroacetate hydrate, metal tetrafluoroborate hydrate, metal perchlorate hexahydrate, and mixtures thereof; alternatively selected from the group consisting of metal alcoxide; alternatively selected from the group consisting of metal propoxide, metal isopropoxide, and mixtures thereof; alternatively selected from the group consisting of Zr(O-i-Pr)₄, Hf(O-i-Pr)₄, Ti(O-i-Pr)₄, Zn(O-i-Pr)₄, Al(O-i-Pr)₄ and mixtures thereof; alternatively selected from the group consisting of Zr(O-i-Pr)₄, Ti(O-i-Pr)₄, Zn(O-i-Pr)₄, and mixtures thereof; alternatively selected from the group consisting of Zr(O-i-Pr)₄, Ti(O-i-Pr)₄, and mixtures thereof. The selection of metal oxide precursors being selected from the group consisting of metal propoxide, metal isopropoxide, and mixtures thereof have shown particularly advantageous, in that they have a good reactivity with methacrylic acid to form metal oxo-clusters with good stability in time and good photosensitivity.

In a preferred embodiment, the metal oxide precursors comprise metal elements selected from the group consisting of Zr, Ti, Zn, and mixtures thereof; and wherein such metal oxide precursors are selected from the group consisting of Zr(O-i-Pr)₄, Ti(O-i-Pr)₄, Zn(O-i-Pr)₄, and mixtures thereof. In another preferred embodiment, the metal oxide precursors comprise metal elements selected from the group consisting of Zr, Ti, and mixtures thereof; and wherein such metal oxide precursors are selected from the group consisting of Zr(O-i-Pr)₄, Ti(O-i-Pr)₄, and mixtures thereof.

The molar ratio ligand:metal may range from about 0.5:1 to about 10:1. The molar ratio ligand:metal is of importance for controlling the morphology of the metal oxo-clusters and their properties. In particular, this parameter is important for controlling the stability of the solution over time, as well as its photosensitivity.

The alcoholic solvent may be selected from the group consisting of propanol, isopropanol, 2-methoxyethanol, ethanol, methanol, dimethylformamide, acetylacetone, dimethylamineborane, acetonitrile, cyclohexane, and mixtures; alternatively selected from the group consisting of propanol, isopropanol, 2-methoxyethanol, ethanol, methanol and mixtures thereof; alternatively the alcoholic solvent is propanol.

It has been shown particularly advantageous selecting metal oxide precursors being selected from the group consisting of metal propoxide, metal isopropoxide, and mixtures thereof, together with the alcoholic solvent being propanol. Indeed, in this case, the solvent corresponds to the molecular species released after complexation of the propoxide precursor by ligand and thus any problem of chemical incompatibility is avoided.

In a particular embodiment, the complexation step is implemented in absence of additives such as acetylacetone, benzoylacetone, ammonium hydroxide.

The present process further comprises the step of preparing a metal oxo-cluster solution by submitting the metal oxide chelate solution to water hydrolysis. This step is called herein “partial condensation step”. It is obtained a partially-condensed metal oxide chelate. This step is important for completing the formation of metal oxo-clusters and for modifying their surface chemistry, which allows having hydroxile groups driving up the adhesion of the material onto hydrophilic substrates such as silicon or glass.

The partial condensation step may be implemented by adding water (acid or basic conditions) to the metal oxide chelate solution, with molar ratio metal:water being comprised between about 1:0.1 and about 1:1000, then stirring the mixture obtained from about 1 min to about 60 min.

The present process may further comprise the step of aging the metal oxo-cluster solution from about 10 min to about 48 h, after carrying out the partial condensation step. This step is called herein “aging step”. Implementing an aging step is recommended for obtaining metal oxo-clusters in solution, as their formation reaction may be a slow process. The addition of an aging step (and therefore the application a sufficient aging time) would help the solution to spread on the substrate (dewetting) and to adhere well on the substrate.

The present process may further comprise the step of adding further alcoholic solvent in the metal oxo-cluster solution, obtained after the partial condensation step or the aging step. This step is called herein “addition step”. Suitable alcoholic solvents are defined hereinbefore. This addition step allows adapting the viscosity of the metal oxide chelate solution.

The viscosity of the metal oxide chelate solution may range from to about 1 cP to about 500 cP.

The present process further comprises the step of preparing a doped-metal oxide chelate solution by doping the metal oxo-cluster solution with a doping material comprising a metal element. This step is called herein “doping step”. It is obtained a doped-metal oxide chelate solution.

The doping step may be implemented by adding the doping material to the metal oxo-cluster solution, then stirring the obtained mixture from about 1 min to about 60 min.

The doping material comprises a metal precursor, wherein the metal precursor may be selected from the group consisting of indium (In), gallium (Ga), tin (Sn), thallium (Tl), copper (Cu), aluminium (Al), and mixtures thereof; alternatively wherein the metal element may be indium (In). The provision of a doping material comprising these metal elements, particularly indium (In), has shown particularly advantageous in that it leads to materials with interesting semiconducting properties, especially in terms of mobility. Moreover, In precursors have proven to limit the alteration of the photosensitivity of the oxo-cluster host matrix, allowing, unlike other materials, high-resolution photolithography.

The doping material may be selected from the group consisting of metal nitrate, metal chloride, metal chloride tetrahydrate, metal fluoride, metal fluoride trihydrate, metal hydroxide, metal acetate hydrate, metal acetylacetonate, metal acetate, metal chloride pentahydrate, metal cyclopentadienide, metal formate, metal hexafluoroacetylacetonate, metal trifluoroacetate, metal perchlorate hydrate, and mixtures thereof; alternatively the doping material may be metal nitrate. The provision of these doping material, particularly a doping material being a metal nitrate, has shown particularly advantageous in that nitrate metals undergo photolysis under DUV that contributes to the formation of an homogeneous metal oxide polymetal network associated with good electrical properties.

In a particular embodiment, the doping material is In(NO₃)₃. The provision of a doping material being In(NO₃)₃ has shown particularly advantageous in that the electrical properties of the matrix doped with In(NO₃)₃ show interesting semi-conducting properties (among them, mobility) that are suitable for practical applications.

The molar ratio between the metal oxide precursor and the doping material having a metal element may range from about 1:0.1 to about 1:10. Particularly, when the metal oxide precursor comprises metal elements selected from the group consisting of Zr, Ti, and mixtures thereof, and when the doping material comprises In as metal element, The molar ratio Zr:In (or Ti:In or (Zr+Ti):In) may range from about 1:0.5 to about 1:5. These ratios have shown particularly advantageous in that it is obtained electrical properties being compatible with practical applications. In particular, the mobility obtained is enough for good semi-conductor properties.

The present process further comprises the step of depositing the doped-metal oxide solution onto a substrate. This step is called herein “deposition step”. It is obtained a substrate coated with a metal oxide thin film.

The technique for depositing the metal oxide thin film onto the substrate may be chosen from the group consisting of spin-coating, dip-coating, spray-coating, inkjet, screen-printing; alternatively the technique for depositing the metal oxide thin film onto the substrate from the group may consist of spin-coating.

The deposition of the metal oxide thin film onto the substrate may be conducted at room temperature, under atmospheric conditions, and under controlled humidity. By “room temperature”, it is meant a temperature ranging from 18° C. to 25° C., preferably a temperature of about 20° C. By “atmospheric conditions”, it is meant an atmospheric pressure ranging from 900 hPa to 1100 hPa, preferably about 1000 hPa. By “controlled humidity”, it is meant a relative humidity ranging from 20% to 60%.

It may be obtained a thin film deposited onto the substrate, wherein said thin film has a thickness ranging from about 10 nm to about 500 nm; preferably from about 20 nm to about 200 nm; more preferably from about 80 nm to about 120 nm. The thickness of the thin film may be measured using ellipsometry.

The substrate may be made of suitable materials. The substrate may be selected from the group consisting of glass, silicon, silicon dioxide, aluminium oxide, sapphire, germanium, gallium arsenide, an alloy of silicon and germanium, indium phosphide, plastic such as polyimide), textiles or their combinations thereof; alternatively the substrate is silicon.

The present process further comprises the step of patterning the coated substrate by irradiating it with deep ultra-violet (DUV) wavelengths. This step is called herein “patterning step”. It is obtained a substrate having a patterned coating.

The technique for irradiating the film substrate may be a spatially-controlled irradiation; alternatively the technique may be photolithography using DUV lamp or lasers; alternatively the technique may be laser direct write lithography or interference lithography.

The use of laser lights has shown advantageous. Indeed, laser lights are directional, thus limiting the diffraction effects. To be specific, the implementation of the irradiation step with a laser emitting DUV wavelengths allows the use of nanolithography, for obtaining semiconductor nanodevices. Indeed, the use of a laser, in comparison with a lamp, avoids, or at least greatly prevents, the occurrence of thermal effects leading particularly to the reticulation of non-irradiated parts of the substrate, leading therefore to a loss of resolution.

In a particular embodiment, the filmed substrate is irradiated via a laser emitting DUV wavelengths. The coated substrate may be irradiated at a UV wavelengths of about 300 nm or less; alternatively at a UV wavelengths ranging from about 180 nm to about 270 nm; alternatively at a UV wavelengths of about 193 nm+/−about 0.5 nm or at a UV wavelengths of about 244 nm+/−about 0.5 nm, or at a UV wavelengths of about 266 nm+/−about 0.5 nm.

UV wavelengths of about 193 nm+/−about 0.5 nm may be obtained using an excimer laser like Braggstar from Coherent, loaded with ArF premix gaz.

UV wavelengths of about 248 nm+/−about 0.5 nm may be obtained using an excimer laser like Braggstar from Coherent, loaded with KrF premix gaz.

UV wavelengths of about 244 nm+/−about 0.5 nm may be obtained using a doubled frequency ion argon laser like Inova 70-C from Coherent.

UV wavelengths of about 266 nm+/−about 0.5 nm may be obtained using a doubled frequency Nd:YAG like Verdi from Coherent.

The metal oxide thin film, coated onto the substrate, is irradiated from 0.01 sec to 1000 sec.

The irradiation may be implemented using masks. Suitable masks may either be shadow masks (e.g. absorbing medium with open parts), metal mask (metal being Chromium, gold, silver . . . ), phase masks, or direct write with focalized beam scanning the surface.

The present process further comprises the step of immersing the substrate comprising a patterned coating into a development media. This step is called herein “development step”. It is obtained a developed patterned substrate.

The development media may be an organic solvent; alternatively the development media may be selected from the group consisting of an alcohol, cyclohexanone, and mixtures thereof; alternatively selected from the group consisting of ethanol, 2-methoxyethanol, propanol, isopropanol, cyclohexanone and mixtures thereof. Alternatively, the development media may be an aqueous solution; alternatively an acid aqueous solution or a basic aqueous solution.

The patterned substrate may be immersed into the organic solvent from 1 sec to 180 sec.

The present process further comprises the step of post-annealing the developed patterned substrate. This step is called herein “post-annealing step”. It is obtained a fully inorganic patterned substrate.

The developed patterned substrate may be post-annealed by thermal and/or photochemical treatment.

The thermal treatment may be carried out at a temperature ranging from about 100° C. to about 800° C.; preferably at a temperature ranging from about 250° C. to about 600° C.; more preferably at a temperature ranging from about 300° C. to about 450° C.

The thermal treatment may be carried out from about 0.1 h to about 2 h; preferably from about 1 h to about 2 h.

The photochemical treatment may be carried out using a DUV light source (lamp/laser), during about 1 sec to about 6 hours; alternatively for about 1 hour.

In a particular embodiment, the thermal treatment and the photochemical treatment are carried out simultaneously.

Prior deposition of the metal oxide thin film onto the substrate, the present process may further comprise the step of treating the surface of the substrate, alternatively the step of functionalizing the surface of the substrate; alternatively the step of functionalizing the surface of the substrate with a treatment preventing dewetting. The treatment preventing dewetting may be selected from the group consisting of UV-ozone treatment, chemical treatment by pirana solution or deposition of a self-assembled monolayer. It is obtained therefore a surface-treated substrate.

Alternatively, prior deposition of the metal oxide thin film onto the substrate, the present process may be free of any step of treating the surface of the substrate. It is provided therefore a non-surface treated substrate.

The present process may be implemented in the absence of photoresists and/or etchants. This is possible as the functional material is integrated by direct writing, which simplifies the process. In particular, etching may be carried out by chemical or physical process, requiring complex setups and aggressive conditions that would be incompatible with delicate substrates. Furthermore, removal of the photoresist on the electrical material may be difficult without the use of a complex process, while the presence of a residual photoresist layer is an issue as it alters the electrical contact between the electrical material and electrodes in a device.

The present process may be free of any step of etching.

Substrates, onto which a patterned metal-oxide thin films is deposited, are obtained with the process described hereinbefore.

It is also obtained semiconductor articles comprising substrates, onto which a patterned metal-oxide thin films is deposited, by implementation of the process described hereinbefore.

### Example

A process for obtaining patterned metal-oxide thin films deposited onto a substrate is detailed hereinafter.

Complexation and Partial Condensation Steps—Preparation of a Metal Oxide Chelate Solution, and then a Metal Oxo-Cluster Solution

For the obtaining of a zirconium oxo-cluster solution, the following materials are provided:
[metal oxide precursor] Zirconium (IV) propoxide solution (70 wt %) in 1-propanol
[ligand] Methacrylic acid (99%)
[alcoholic solvent] 1-propanol (ACS reagent, anhydrous, 99.7%)
hydrochloric acid (ACS reagent, 37%) 1 mL of Zr (IV) propoxide solution and 2 mL of Methacrylic acid are mixed, before agitation for 5 minutes. 2 mL of 1-propanol is then added to the mixture obtained, before agitation for 10 min 0.9 mL of water (HCl=0.37M) is then added, before agitation for 60 min After a 24 h resting time, a determined amount (between about 0 and 8 mL, depending on the film thickness targeted) of 1-propanol is added to the rested mixture, before agitation for 10 min.

For the obtaining of a titanium oxo-cluster solution, the following materials are provided:
[metal oxide precursor] Titanium (IV)-isopropoxide solution (97 wt %)
[ligand] Methacrylic acid (99%)
[alcoholic solvent] 1-propanol (ACS reagent, anhydrous, 99.7%)
hydrochloric acid (ACS reagent, 37%) 1 mL of Zr (IV) propoxide solution and 2 mL of Methacrylic acid are mixed, before agitation between 5 minutes. 2 mL of 1-propanol is then added to the mixture obtained, before agitation for 10 min 0.9 mL of water (HCl=0.37M) is then added, before agitation for 60 min. After a 24 h resting time, a determined amount (between about 0 and 8 mL, depending on the viscosity expected) of 1-propanol is added to the rested mixture, before agitation for 10 min.

Doping Step

The following material is provided:
[doping material comprising a metal element] Indium (III) nitrate hydrate 99.9% trace metal basis

Three doped-metal oxide solutions are prepared, using different molar ratios of Zr (or Ti) and In i.e. ratio 1:1, ratio 1:2 and ratio 1:5 respectively.

For the ratio 1:1, 2 mL of the Zr (or Ti) oxo-cluster solution is mixed with respectively 0.09 mL of Indium (III) nitrate hydrate, before agitation for 24 h.

For the ratio 1:2, 2 mL of the Zr (or Ti) oxo-cluster solution is mixed with respectively 0.18 mL of Indium (III) nitrate hydrate, before agitation for 24 h.

For the ratio 1:1, 2 mL of the Zr (or Ti) oxo-cluster solution is mixed with respectively 0.45 mL of Indium (III) nitrate hydrate, before agitation for 24 h.

Deposition Step

The Zr doped-metal oxide solution is deposited onto a substrate using the spin-coating technique at 6000 rpm for 60 sec. Three different thicknesses are achieved i.e.:
Ratio 1:1—thickness of 47 nm
Ratio 1:2—thickness of 54 nm
Ratio 1:5—thickness of 65 nm.

Thickness is measured by spectroscopic ellipsometry, using an Uvisel Jobin-Yvon ellipsometer (spectral range 190-830 nm).

Patterning, Development and Post-Annealing Steps—Obtaining of a Fully Inorganic Patterned Substrate

The patterning of the coated substrate was carried out, by irradiation with a DUV laser or lamp with binary chromium masks or fused silica phase masks. It is used either a DUV laser being ArF laser (Braggstar from Coherent) emitting at 193 nm, or a DUV lamp being a Hamamatsu LC8 high intensity mercury—xenon lamp equipped with a waveguide.

The following material is provided:
[Development media] cyclohexone and ethanol, in a volumic ratio of 9:1, with Cyclohexanone (ACS reagent, >99.0%)

Obtaining of a fully inorganic patterned film, by irradiation using a UV lamp (Zr, Ti), was carried out as follows:
Irradiation time of 15 sec for the doped-metal oxide solution (ratio 1:1); 30 sec for the doped-metal oxide solutions (ratio 1:2); 30 sec for the doped-metal oxide solutions (ratio 1:5); then
Development with cyclohexone/ethanol (ratio of 9:1) for 30 sec; then
Post-annealing for 1 hour at 400° C.

Obtaining of a fully inorganic patterned film (Zr) with periodic patterns of 600 nm, by irradiation using a UV laser, was carried out as follows:
Irradiation of the In-doped ZrO₂ solution at 25 mJ, for a laser delivering 2 mW; then
Development with cyclohexanone for 30 sec; then
Post-annealing for 1 hour at 400° C.

Obtaining of a fully inorganic patterned film (Ti) with periodic patterns of 600 nm, by irradiation using a UV laser, was carried out as follows:
Irradiation of the In-doped TiO₂ solution at 10 mJ, for a laser delivering 2 mW; then
Development with cyclohexone for 30 sec; then
Post-annealing for 1 hour at 400° C.

Mask Lithography

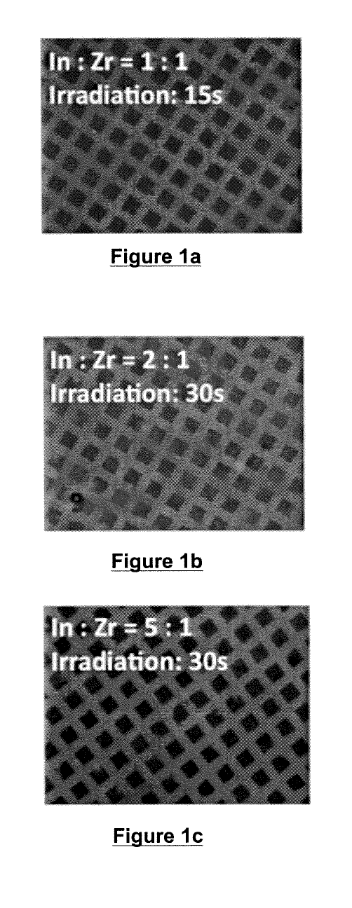

In FIGS. 1a, 1b and 1c, it is shown patterned metal-oxide thin films deposited onto the substrate (30×30 micron squares), when using three In-doped ZrO₂ solutions are prepared, using respectively the Zr:In molar ratios of 1:1 (FIG. 1a), 1:2 (FIG. 1b) and 1:5 (FIG. 1c).

Laser Interferometry Lithography

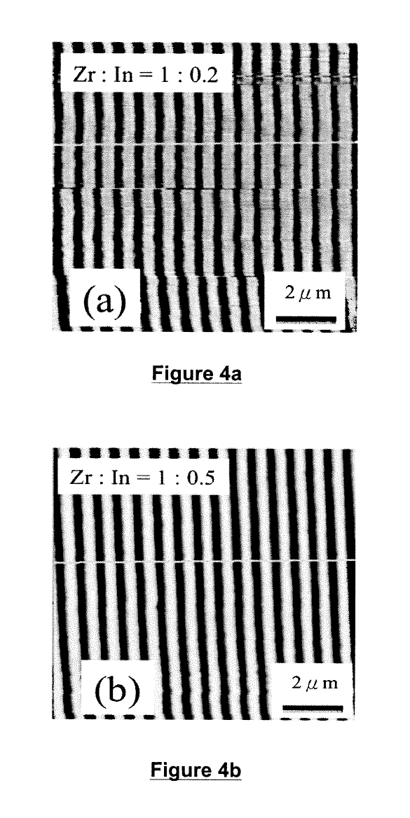

In FIGS. 4a and 4b, it is shown patterned metal-oxide thin films deposited onto the substrate, when using two In-doped ZrO₂ solutions prepared using respectively the Zr:In molar ratios of 1:0.2 (FIG. 4a), and 1:0.5 (FIG. 4b).

Effect of in-Doping on Electrical Properties

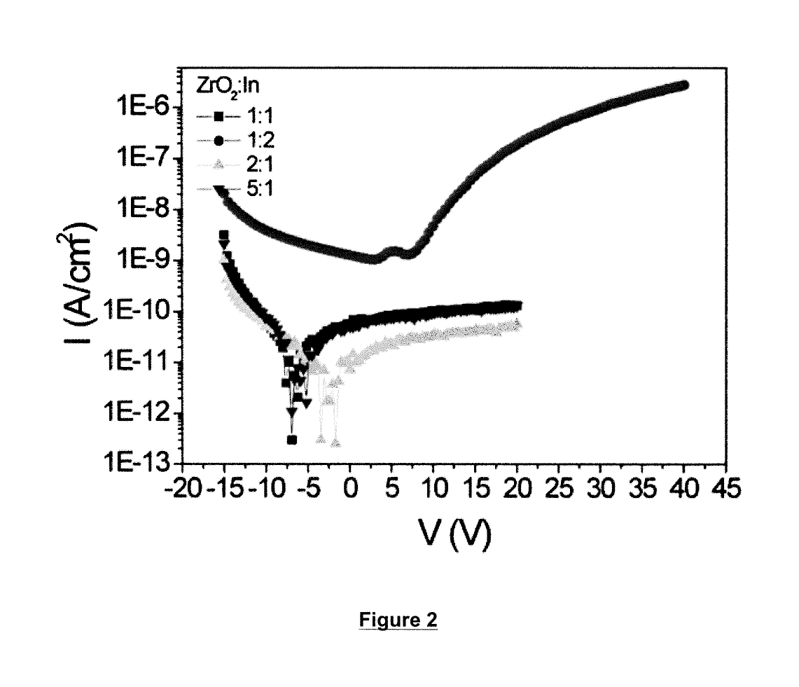

The electric properties of metal-oxide thin films deposited, when using four In-doped ZrO₂ solutions (respectively molar ratios 1:1, 1:2, 2:1, 5:1), have been assessed. Thermal annealing of the samples have been carried out at 400° C. Particularly, it has been measured the electric current density (A/cm2) in function of the voltage (V). FIG. 2 is a graphic representation of the measurements made on three of metal-oxide thin films deposited onto the substrate, for In-doped ZrO₂ solutions.

Effect of Curing Temperature

The effect of the curing temperature of metal-oxide thin films deposited, when using an In-doped ZrO₂ solution at molar ratio 1:2, has been assessed. Particularly, it has been measured ABSID (which represents the absolute value of drain current with the unit as ampere) in function of SQRTID (A^{0.5}) (which represents the square root of the absolute value of the drain current, with the unit as the square root of ampere).

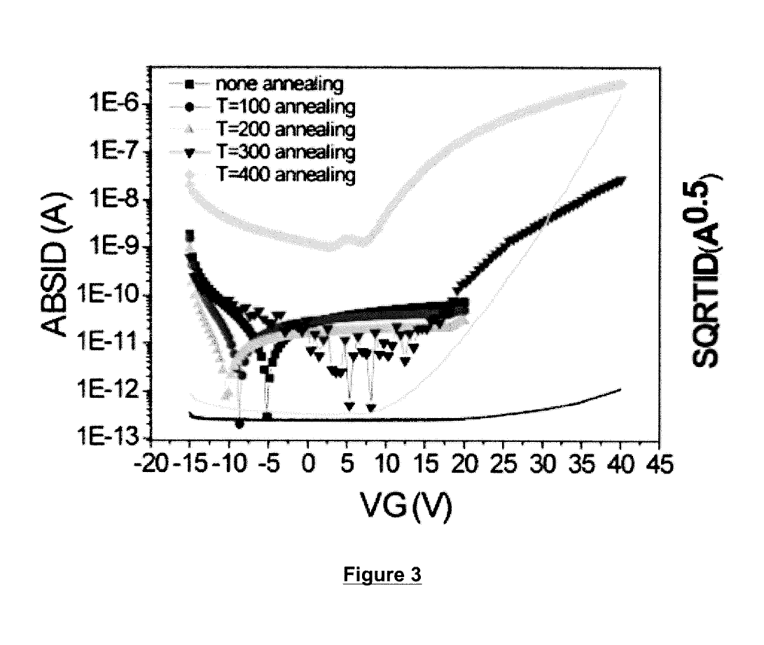

FIG. 3 is a graphic representation of the measurements made on In-doped ZrO₂ solutions (1:2) and represents the experimental transfer characteristics from preliminary tests. The plots show the absolute value of the drain current (in log scale, Ampere) and the square root of the absolute value of the drain current (square root of Ampere) in function of the gate voltage (Volt).

The data obtained show that for temperature higher than 300° C., semi-conducting properties are obtained. Mobility as 0.03 cm2/Vs was obtained.

To be specific, the following data were obtained with an annealing temperature of 400° C.

| | | | | μ | μ max | | |
|---|---|---|---|---|---|---|---|
| | Length | VT | Von | (cm²/ | (cm²/ | S.S. | |
| Sample | (μm) | (V) | (V) | Vs) | Vs) | (V/dec.) | On/Off |
| 400 | 300 | 14.02 | 7 | 0.03 | 0.05 | 4.95 | 2.10E+03 |
| anneal. | | | | | | | |

The table lists some typical parameters of a InZrOx TFT fabricated by using the proposed method with a following 400 C thermal annealing. The transistor demonstrates normal on and off operation with mobility as 0.03 cm2/Vs. The results show the feasibility to realize TFT by using the proposed material and the proposed process.

1. A process for obtaining a semiconductor nanodevice comprising a substrate onto which patterned metal-oxide thin films having semiconductor properties are deposited, said process comprising the steps of:
preparing a metal oxide chelate solution by complexing metal oxide precursors with a ligand in an alcoholic solvent for obtaining a metal oxide chelate; wherein the ligand is methacrylic acid; and wherein the metal oxide precursors comprise metal elements selected from the group consisting of zirconium (Zr), titanium (Ti), zinc (Zn), and mixtures thereof;
preparing a metal oxo-cluster solution by submitting the metal oxide chelate solution to water hydrolysis, for obtaining a partially-condensed metal oxide chelate;
preparing a doped-metal oxide solution by doping the metal oxo-cluster solution with a doping material comprising a metal element;
depositing the doped-metal oxide solution onto a substrate, for obtaining a substrate coated with a metal oxide thin film;
patterning the coated substrate by irradiating it with deep ultra-violet (DUV) wavelengths, for obtaining a patterned coating; wherein the coated substrate is irradiated via a laser emitting DUV wavelengths;
immersing the substrate comprising a patterned coating into a development media, for obtaining a developed patterned substrate;
post-annealing the developed patterned substrate, for obtaining a fully inorganic patterned substrate.

2. The process, according to claim 1, wherein the metal oxide precursors are selected from the group consisting of Zr(O-i-Pr)₄, Ti(O-i-Pr)₄, Zn(O-i-Pr)₄, and mixtures thereof.

3. The process, according to claim 1, wherein the doping material comprises a metal element selected from the group consisting of indium (In), gallium (Ga), tin (Sn), thallium (Tl), copper (Cu), aluminium (Al), and mixtures thereof; preferably wherein the metal element is In.

4. The process, according to claim 1, wherein the doping material is selected from the group consisting of metal nitrate, metal chloride, metal chloride tetrahydrate, metal fluoride, metal fluoride trihydrate, metal hydroxide, metal acetate hydrate, metal acetyl acetonate, metal acetate, metal chloride pentahydrate, metal cyclopentadienide, metal formate, metal hexafluoroacetylacetonate, metal trifluoroacetate, metal perchlorate hydrate, and mixtures thereof; preferably wherein the doping material is metal nitrate.

5. the process, according to claim 1, wherein the doping material is In(NO₃)₃.

6. The process, according to claim 1, wherein the alcoholic solvent is selected from the group consisting of propanol, isopropanol, 2-methoxyethanol, ethanol, methanol, dimethylformamide, acetylacetone, dimethylamineborane, acetonitrile, cyclohexane, and mixtures; alternatively selected from the group consisting of propanol, isopropanol, 2-methoxyethanol, ethanol, methanol and mixtures thereof.

7. The process, according to claim 1, wherein the technique for depositing the metal oxide thin film onto the substrate is chosen from the group consisting of spin-coating, dip-coating, spray-coating, inkjet, screen-printing; alternatively wherein the technique for depositing the metal oxide thin film onto the substrate is chosen from the group consisting of spin-coating.

8. The process, according to claim 1, wherein the deposition of the metal oxide thin film onto the substrate is conducted at room temperature, under atmospheric conditions, and under controlled humidity.

9. claim 1 process, according to claim 1, wherein the thin film deposited onto the substrate has a thickness ranging from 10 nm to 500 nm; preferably from 20 nm to 200 nm; more preferably from 80 nm to 120 nm.

10. The process, according to claim 1, wherein the substrate is made of materials selected from the group consisting of glass, silicon, silicon dioxide, aluminium oxide, sapphire, germanium, gallium arsenide, an alloy of silicon and germanium, indium phosphide, plastic such as polyimide), textiles or their combinations thereof; alternatively the substrate is silicon.

11. The process, according to claim 1, wherein the technique for irradiating the film substrate is a spatially-controlled irradiation; preferably the technique is photolithography using DUV lamp or lasers; more preferably the technique is laser direct write lithography or interference lithography.

12. The process, according to claim 1, wherein the coated substrate is irradiated at a UV wavelengths of 300 nm or less; preferably at a UV wavelengths ranging from 180 nm to 270 nm; more preferably at a UV wavelength of 193 nm+/−0.5 nm or alternatively at a UV wavelength of 244 nm+/−0.5 nm, or alternatively at a UV wavelength of 266 nm+/−0.5 nm.

13. The process, according to claim 1, wherein the development media is an organic solvent; preferably an alcohol, cyclohexanone, and mixtures thereof; more preferably wherein the organic solvent is selected from the group consisting of ethanol, 2-methoxyethanol, propanol, isopropanol, cyclohexanone and mixtures thereof.

14. The process, according to claim 1, wherein the patterned substrate is immersed into the organic solvent from 1 sec to 180 sec.

15. The process, according to claim 1, wherein the developed patterned substrate is post-annealed by thermal and/or photochemical treatment.

16. A semiconductor device comprising a substrate, onto which a patterned metal-oxide thin films is deposited, said patterned thin-film being obtained with the process according to claim 1.
